(19) United States
(12) Patent Application Publication
(10) Pub. No.: US 2007/0071056 A1
(43) Pub. Date: Mar. 29, 2007

(54) Laser ranging with large-format VCSEL array

(76) Inventor: Ye Chen, Loveland, CO (US)

Correspondence Address: AVAGO TECHNOLOGIES, LTD., P.O. BOX 1920, DENVER, CO, 80201-1920, US

(21) Appl. No.: 11/223,329

(22) Filed: Sep. 9, 2005

(51) Int. Cl. H01S 5/00

(52) U.S. Cl. 372/50.124

(57) ABSTRACT

The present invention relates to laser ranging and detection by sequentially emitting a plurality of beams from a vertical-cavity surface-emitting laser (VCSEL) structure, re-directing the beams through optical elements such that they are fanned out over the region of view, and detecting any beams that may be reflected by objects in the region of view. The range and bearing of such objects can be determined from the beam time-of-flight and beam angle.

### BACKGROUND OF THE INVENTION

There has been significant interest in automotive vehicle collision avoidance systems that use LIDAR (Light Detection And Ranging) to detect obstacles. Similar laser-based detection systems have been developed in other fields as well. In a typical example of a LIDAR or laser-based obstacle-detection system for automobiles, a mechanically operated mirror sweeps or scans a laser beam across a region of view. An object in the region of view reflects the beam, which is then detected by an optoelectronic detector. The laser, mirror assembly, and detector are all contained in a unit mounted in the front end of the automobile. By pulsing the laser and timing the difference between emitting a pulse and detecting a reflected pulse, the system can calculate the range to the object. Also, by determining the relative positions of the mirror at the time the pulses were emitted and detected, the system can determine the bearing of the object. Uses for such systems that have been suggested and developed to varying extents include automatic braking for collision avoidance, parking assistance, turning assistance and cruise control.

Although the above-described laser ranging system may work well in experimental installations, a system having relatively delicate opto-mechanical parts such as a rotating mirror may not be sufficiently rugged and durable for long-term reliability in an automobile or similar vehicle under typical use conditions. Furthermore, rotating mirrors and similar opto-mechanical assemblies may not be sufficiently economical for widespread commercial acceptance.

It would be desirable to provide a laser ranging system that is rugged, reliable and economical. The present invention addresses the above-described problems and deficiencies and others in the manner described below.

### SUMMARY OF THE INVENTION

The present invention relates to laser ranging- by sequentially emitting a plurality of beams from a vertical-cavity surface-emitting laser (VCSEL) structure, re-directing the beams through optical elements such that they are fanned out over the region of view, and detecting any beams that may be reflected by objects in the region of view.

In an exemplary embodiment of the invention, the optical elements can comprise microlenses that are either integrally formed with the VCSEL structure or as a separate structure bonded or otherwise attached to the VCSEL structure. This embodiment may be especially economical and reliable, as the lasers and microlenses together form a unitary and solid structure, relatively immune to damage from vibration and other hazards of an automotive environment. By arraying the laser sources at some suitable predetermined pitch (i.e., distance between adjacent ones in the array) and arraying the corresponding microlenses at a slightly different predetermined pitch, the beam emitted from each laser source in the array Will be directed at a slightly different angle than the immediately adjacent laser source in the array. In this manner, the beams originating from a relatively small VCSEL chip can be fanned out over a considerably greater region of view.

### BRIEF DESCRIPTION OF THE DRAWINGS

FIG. 1 is a generalized depiction of a VCSEL-based ranging system.

FIG. 2 is a generalized perspective view of the emitting structure of an alternative VCSEL-based ranging system having a three-dimensional region of view.

FIG. 3 is a generalized sectional view of a portion of the VCSEL-based emitting structure of the system of FIG. 1.

FIG. 4 is a top view of an alternative microlens for an emitting structure.

FIG. 5 is sectional view of the alternative microlens of FIG. 4.

FIG. 6 is a generalized sectional view, similar to FIG. 3, of a portion of an alternative VCSEL-based emitting structure having the alternative microlenses of FIG. 4.

FIG. 7 illustrates a step of a method for making a microlens array.

FIG. 8 illustrates another step in the method of FIG. 7.

FIG. 9 illustrates a step of an alternative method for making a microlens array.

FIG. 10 illustrates another step in the method of FIG. 9.

FIG. 11 illustrates still another step in the method of FIGS. 9-10.

FIG. 12 illustrates a step of another alternative method for making a microlens array.

FIG. 13 illustrates another step in the method of FIG. 12.

FIG. 14 illustrates still another step in the method of FIGS. 12-14.

FIG. 15 is a generalized sectional view an exemplary of one of the laser sources of the emitting structure of the system of FIG. 1.

FIG. 16 is a flowchart illustrating a method for making the system of FIG. 1.

FIG. 17 is a generalized diagram illustrating the ranging system of FIG. 1 in use in an automobile.

FIG. 18 is a flowchart illustrating a method of operation of the ranging system of FIG. 1.

FIGS. 19A-19D illustrate the emitting structure of the system of FIG. 1 emitting beams in a scan-like sequence.

### DETAILED DESCRIPTION OF PREFERRED EMBODIMENTS

In the following description, like reference numerals indicate like components to enhance the understanding of the invention through the description of the drawings. The drawing figures are not to scale. Also, although specific features, configurations, arrangements and steps are discussed below, it should be understood that such specificity is for illustrative purposes only. A person skilled in the relevant art will recognize that other features, configurations, arrangements and steps are useful without departing from the spirit and scope of the invention.

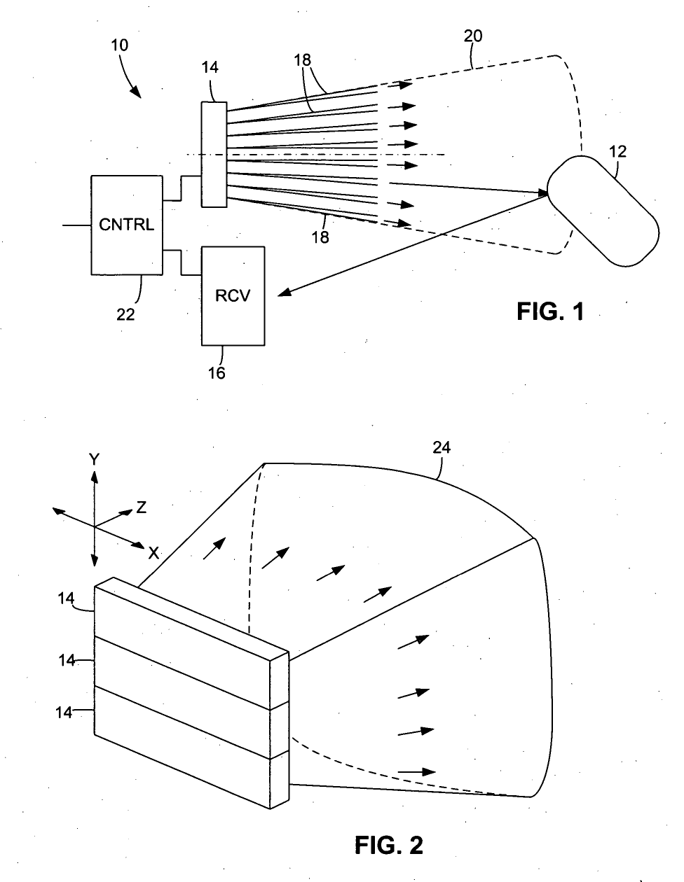

As illustrated in FIG. 1, a laser ranging apparatus 10 that can detect the distance (range) and location (bearing) of objects 12 includes a vertical-cavity surface-emitting laser (VCSEL)-based emitting structure 14 and a receiving structure 16. Emitting structure 14 emits a number of laser beams 18 that fan out over a region of view 20 of several meters. The beams, which are represented in FIG. 1 in the far-field of region of view 20 by arrows, may be reflected off objects 12 in the far-field. Receiving structure 16 receives and detects beams 18 reflected toward it by such objects 12, as described below in further detail. Control electronics 22 controls the system, as also described below in further detail.

Emitting structure 14 can emit any suitable number of beams 18, and the number illustrated in FIG. 1 is intended only to be exemplary and for purposes of illustration. For example, it is contemplated that emitting structure 14 be capable of emitting on the order of 50 to 100 beams 18 in embodiments of the invention that relate to an automotive ranging system, as described in further detail below. It is also contemplated that region of view 20 extend on the order of 10-50 meters from emitting structure 14 in such embodiments. Nevertheless, in other embodiments the emitting structure can emit any suitable number of beams and provide any suitable region of view.

As illustrated in FIG. 2, a greater region of view 24 can be covered by assembling a plurality of VCSEL-based emitting structures 14. The resulting assembly can be included in the system illustrated in FIG. 1 in place of the single emitting structure 14. Note that region of view 24 fans out not only horizontally but also vertically to some extent.

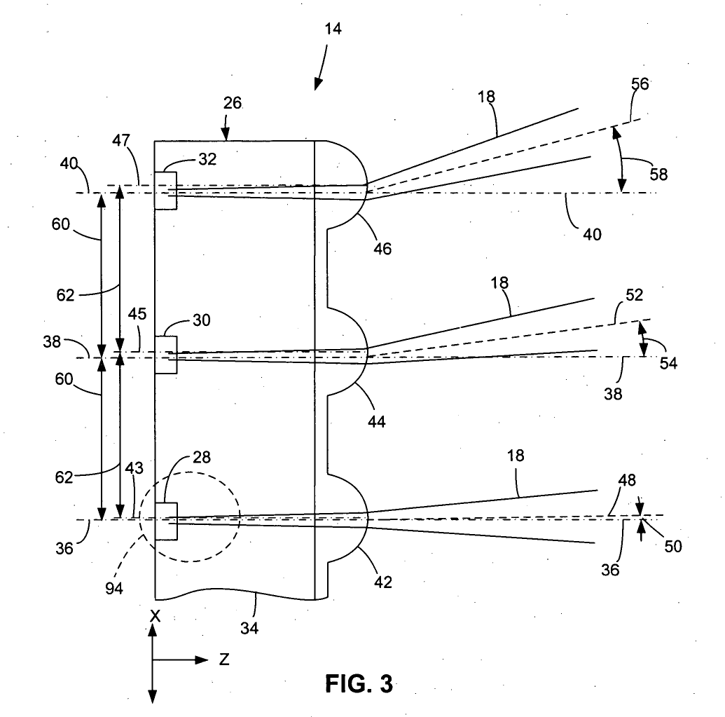

As illustrated in FIG. 3, emitting structure 14 includes a VCSEL structure 26 having a number of laser sources 28, 30, 32, etc., formed on a semiconductor substrate 34 (e.g., Si—GaAs) in a linear array. As known in the art, a VCSEL is a microelectronic structure in which a laser is formed on a substrate using conventional photolithographic fabrication methods, as described in further detail below. Substrate 34 is generally planar, as represented by the plane defined by the X-Y axes shown in FIG. 2. A defining characteristic of a vertical cavity surface-emitting laser (VCSEL) is that the laser cavity axis is substantially normal or “vertical” to this plane of substrate 34, i.e., oriented in the direction of the Z axis shown in FIGS. 2 and 3. In the illustrated embodiment, laser sources 28, 30, 32, etc., are oriented along respective axes 36, 38, 40, etc., and the beams 18 they emit are initially directed along these axes.

Although beams 18 are initially aligned with axes 36, 38, 40, etc., a corresponding number of optical elements 42, 44, 46, etc., re-direct beams 18 in a lens-like manner to fan beams 18 out over region of view 20 as described above with regard to FIG. 1. Note that the fan-shape of region of view 20 is the result of no beam 18 being emitted from emitting structure 14 parallel to any other beam 18. Each beam 18 shown in FIG. 3 is redirected at a different angle. The beam 18 that is initially aligned with axis 36 is redirected along an axis 48 at an angle 50 with respect to axis 36. The beam 18 that is initially aligned with axis 38 is redirected along an axis 52 at an angle 54 with respect to axis 38. The beam 18 that is initially aligned with axis 40 is redirected along an axis 56 at an angle 58 with respect to axis 40. Note that angle 58 is greater than angle 54, and angle 54 is greater than angle 50, and so forth. In this fashion, the angle at which the beam 18 that is emitted by each successive laser source along the array is redirected is slightly greater than the angle at which the beam 18 emitted by the preceding laser source in the array is redirected. It can similarly be noted that beams 18 emitted by any two adjacent laser sources are redirected at angles closer to one another than beams 18 emitted by two non-adjacent laser sources.

Successive beams 18 along the array can be made to be emitted at successively greater angles in any suitable manner. In embodiments of the invention in which optical elements 42, 44, 46, etc., are spherical microlenses, one suitable method is to form laser sources 28, 30, 32 at a first predetermined spacing or pitch 60, and to form optical elements 42, 44, 46, etc., at a second predetermined spacing or pitch 62 that is slightly greater than the first. The pitch 62 between successive (spherical microlens) optical elements 42, 44, 46, etc., is defined by the distance between their adjacent optical axes 43, 45, 47, etc. As well-known in the art, a microlens is a type of lens that can be formed using photolithographic techniques on a suitable substrate. Such techniques are particularly suitable for forming repetitive structures, such as microlenses, that are separated by a pitch. Patterns that repeat at that pitch can readily be formed on an optical mask. Using the mask to expose the microlens material and etching the exposed material in the conventional manner results in microlens structures formed with the submicron precision needed to achieve proper optical alignment. Although the fabrication of microlenses is in itself well-understood in the art, it is described in further detail below specifically with regard to their fabrication upon VCSEL structure 26.

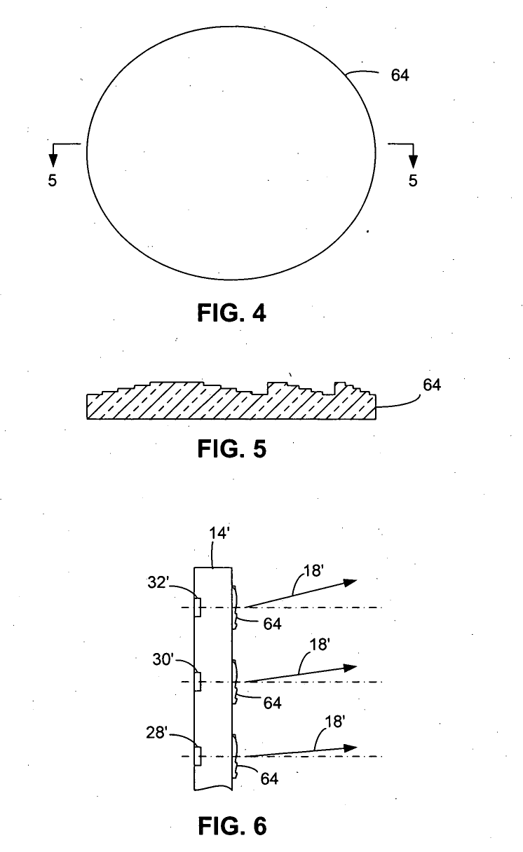

In other embodiments of the invention, another way of fanning the beams out, i.e., steering successive beams along the array at successively greater angles, is to employ binary diffractive microlenses 64 as the optical elements, as illustrated in FIGS. 4 and 5. A surface relief pattern is lithographically transferred to a glass substrate, which is then etched using a suitable technique, such as ion beam etching. The etching step produces a two-level surface, giving rise to the term “binary” optics. The etching step can be repeated to create the illustrated multi-level surface. In embodiments of the invention in which binary diffractive lenses are employed as the optical elements, they do not need to be spaced at a pitch that is different from the pitch at which the laser sources are spaced. An embodiment of such an emitting structure 14′ is illustrated in FIG. 6, in which binary diffractive lenses 64 direct beams 18′ emitted by successive laser sources 28′, 30′, 32′, etc., along the array at successively greater angles to form the fan pattern. Although illustrated as formed on separate substrates, in other embodiments it may be possible to etch binary diffractive microlenses 64 into the same substrate as that in which the laser sources are formed.

Still other ways of fanning the beams out over the region of view can be employed in still other embodiments of the invention. For example, the beams can be redirected at angles that are not successively greater along the array but rather change from one to the next in some other manner. Indeed, the angles at which the various beams are redirected can be randomly selected, with no predetermined pattern from one to the next along the array, so long as they collectively are fanned out to cover a region of view.

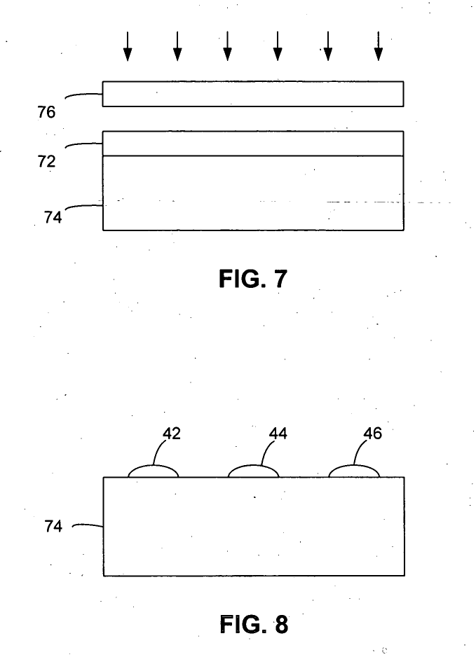

Another suitable microlens fabrication method that can be used to make optical elements 42, 44, 46, etc., is known as grayscale lithography and is illustrated in FIGS. 7 and 8. As illustrated in FIG. 7, a suitable photosensitive material 72 is deposited on a glass or semiconductor substrate 74. Substrate 74 can be the same substrate 34 (FIG. 3) upon which laser sources 28, 30, 32, etc., are formed, or it can be a separate element that is later bonded to substrate. 34. Then, photosensitive material 72 is exposed through a mask 76. Following an etching step in which the surrounding photosensitive material 72 is removed, optical elements 42, 44, 46, etc., are left.

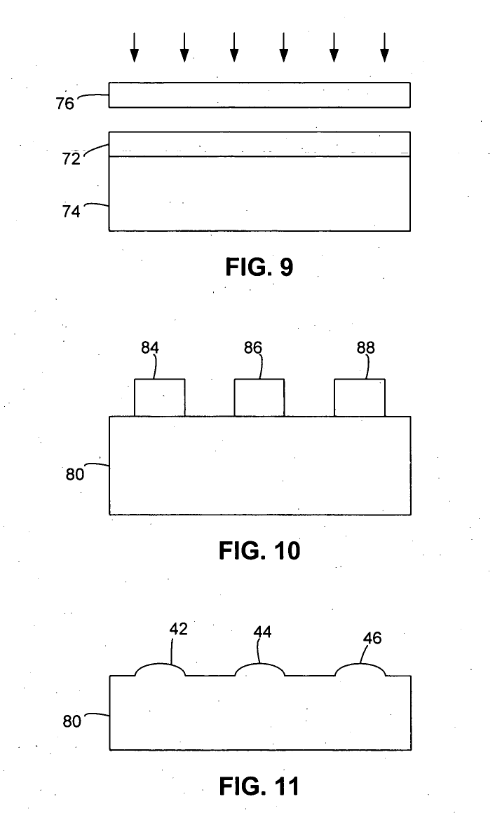

Still another suitable microlens fabrication method that can be used to make optical elements 42, 44, 46, etc., is illustrated in FIGS. 9-11. As illustrated in FIG. 9, a suitable photosensitive material 78 is deposited on a glass or semiconductor substrate 80. Substrate 80 can be the same substrate 34 (FIG. 3) upon which laser sources 28, 30, 32, etc., are formed, or it can be a separate element that is later bonded to substrate 34. Exposing photosensitive material 78 through a mask 82 having circular patterns and performing an etching step leaves cylinders 84, 86, 88, etc. A reflow step is then performed, causing cylinders 84, 86, 88, etc., to transform into spherical shapes, as illustrated in FIG. 10. A final etching step transfers the spherical shapes into substrate 80, as illustrated in FIG. 11. As known in the art, mask 82 determines the footprint of the resulting microlenses, and the thickness of photosensitive material determines the sag or volume of each microlens. The shape of the microlens can be controlled through the difference in etching rate between substrate 80 and photosensitive material 78.

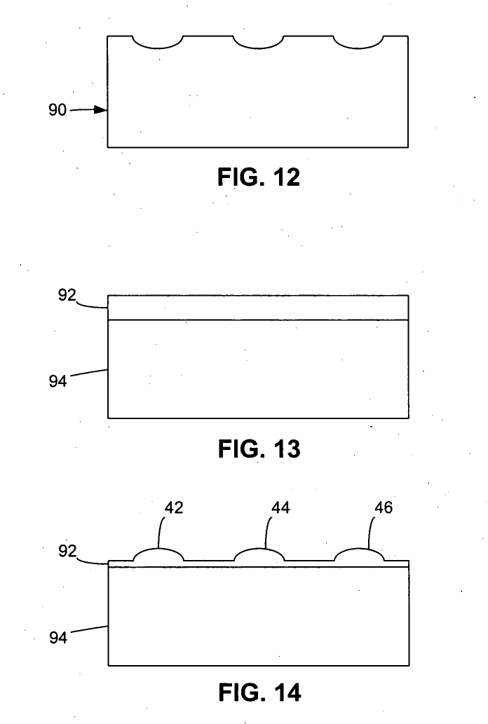

Yet another suitable microlens fabrication method that can be used to make optical elements 42, 44, 46, etc., is illustrated in FIGS. 12-14. As illustrated in FIG. 12, a microlens array fabricated in accordance with one of the etching-based methods described above or other suitable method is used to make a negative master 90. A suitable polymer material 92 is deposited on a glass or semiconductor substrate 94, as illustrated in FIG. 13. Substrate 94 can be the same substrate 34 (FIG. 3) upon which laser sources 28, 30, 32, etc., are formed, or it can be a separate element that is later bonded to substrate 34. Negative master 90 is then used to stamp positive shapes in polymer material 92, as illustrated in FIG. 14, thereby replicating the shape of the original microlens array. Still other methods for fabricating optical elements 42, 44, 46, etc., will occur to person skilled in the art in view of these teachings.

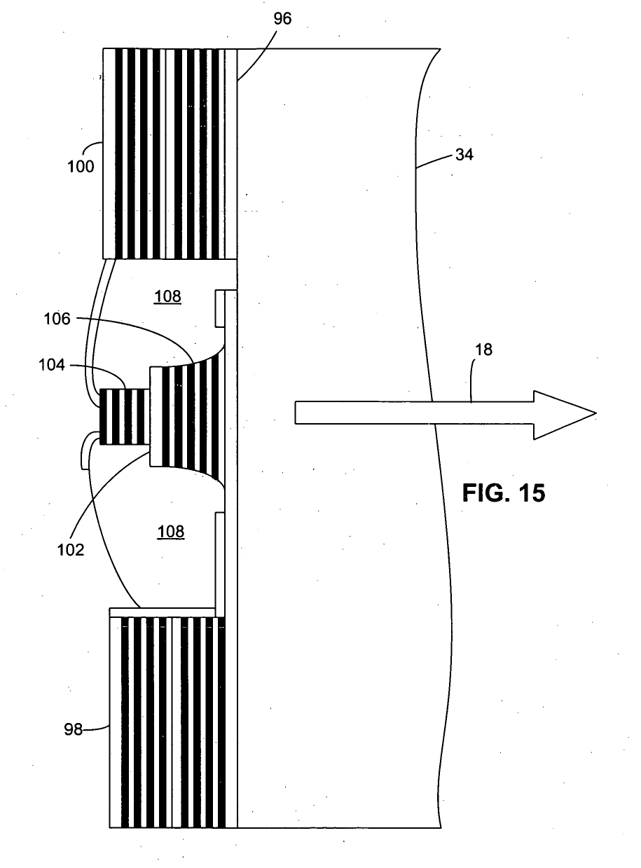

The area enclosed in the dashed-line circle 94 in FIG. 3 is a region of VCSEL structure 26 in the vicinity of an exemplary one of laser sources 28, 30, 32, etc. and is illustrated in further detail in FIG. 15. Such a VCSEL laser source is well-known in the art and therefore described only briefly in this patent specification. The illustrated VCSEL is known as a bottom-emitting VCSEL because it emits beam 18 through substrate 34, which is the “bottom” of the overall monolithic VCSEL structure 26 (see FIG. 3). (Note that the VCSEL is illustrated in the vertical orientation in which it is disposed in FIG. 3 for purposes of consistency among the drawing figures, even though a VCSEL is typically conventionally illustrated in a horizontal orientation.)

Substrate 34 can be made of Si—GaAs or other suitable material, as known in the art. Upon (the “top” of) substrate 34 is deposited an N—GaAs buffer layer 96. Adjoining a central circular area are an N-contact 98 and a P-contact 100, formed in the conventional manner. An active area 102 is sandwiched between top and bottom distributed Bragg reflector (DBR) stacks 104 and 106, respectively, in the middle of the central circular area. A generally annular polyimide bridge 108 surrounds active area 102 and DBR stacks 104 and 106. Although bottom-emitting in the illustrated embodiment, the same VCSEL can be made to be top-emitting, as known in the art.

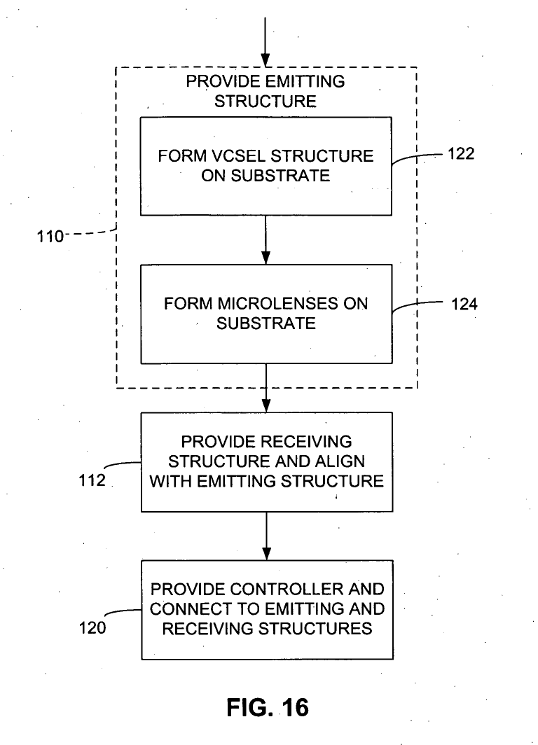

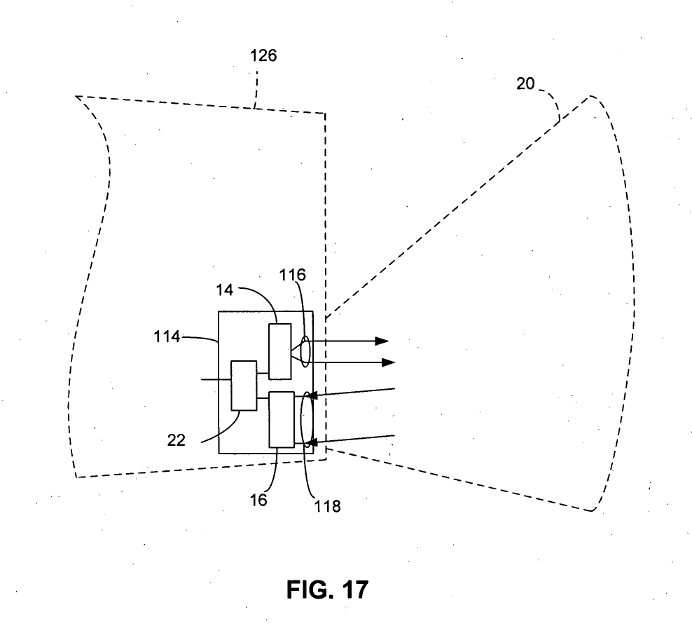

In summary, an exemplary method for making laser ranging apparatus 10 is illustrated in FIG. 16. At step 110, emitting structure 14 is provided, and at step 112, receiving structure 16 is provided. As illustrated in FIG. 17, structures 14 and 16 are mounted in a suitable enclosure 114 and optically aligned so that receiving structure 16 can detect beams reflected by objects in region of view 20 (see also FIG. 1). Additional macro-scale lenses 116 and 118 for structures 14 and 16, respectively, can be mounted in enclosure 114 to enhance emission and collection efficiency. Returning to FIG. 16, at step 120 controller 22 is provided and electrically connected to emitting and receiving structures 14 and 16. Step 110 comprises steps 122 and 124 of forming VCSEL structure 26 and optical elements (e.g., microlenses) 42, 44, 46, etc., respectively, on substrate 34 (see FIG. 3).

Referring again to FIG. 17, the novel laser ranging apparatus 10 of the present invention is mounted in the front end (or other suitable region) of an automobile 126 and can be connected to any suitable conventional electronic system (not shown) for aiding collision avoidance, parking assistance, turning assistance, cruise control or any other function for which conventional laser-based ranging systems have been used in the prior art.

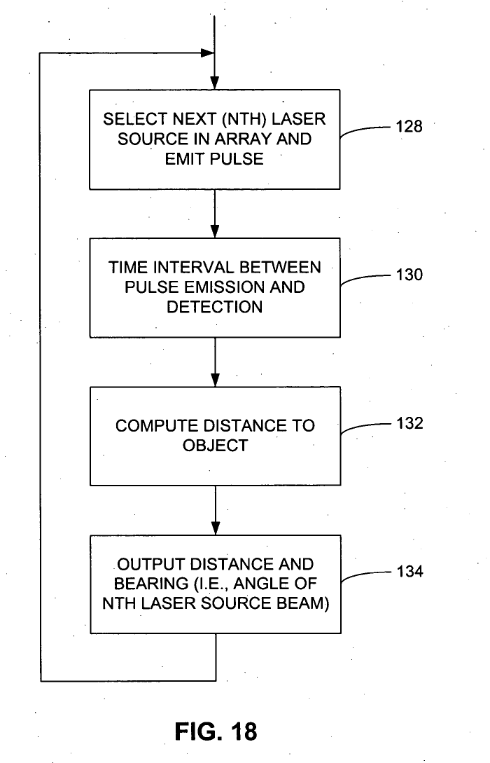

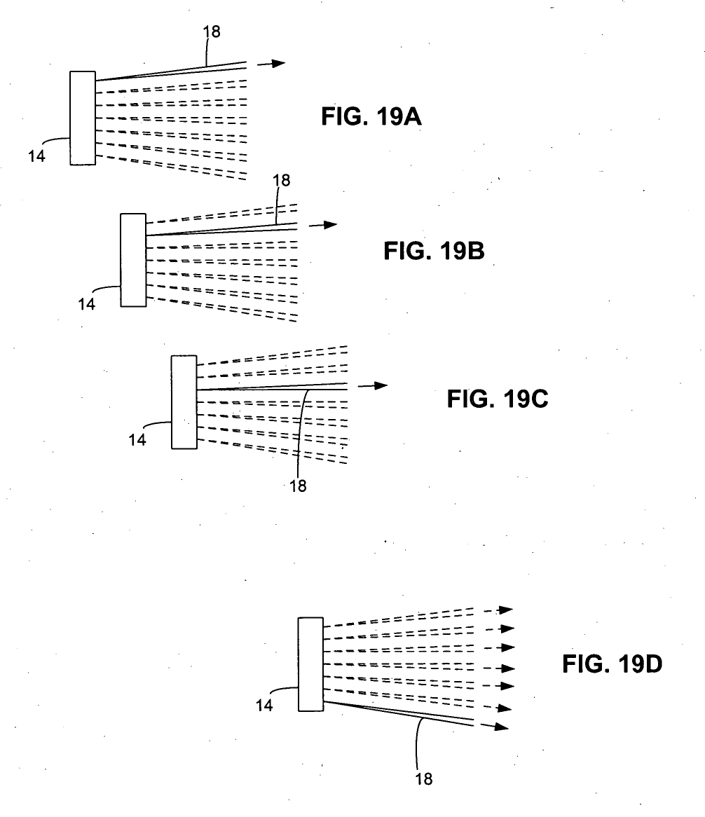

An exemplary method of operation for laser ranging apparatus 10 that can be effected under the control of controller 22 (FIGS. 1 and 16) is illustrated in FIG. 18. Referring briefly to FIGS. 19A-19D, controller 22 sequentially selects and activates the successive laser sources in the array of emitting structure 14. In other words, a beam 18 in the form of a pulse or short pulse train is emitted from a first laser source in the array in emitting structure 14, as illustrated in FIG. 19A. Then, a beam 18 in the form of a pulse or short pulse train is similarly emitted from a second laser source in the array in emitting structure 14, as illustrated in FIG. 19B. A beam 18 in the form of a pulse or short pulse train is then emitted from a third laser source in the array in emitting structure 14, as illustrated in FIG. 19C,.and so on, until a beam 18 is emitted from the last laser source in the array in emitting structure 14, as illustrated in FIG. 19D. The next beam 18 to be emitted will be from the first laser source, as the cycle continues in an essentially continuous manner, with beams 18 sweeping through region of view 20 (see FIG. 1).

Thus, returning to FIG. 18, at step 128 controller 22 selects and activates the first laser source in the array of emitting structure 14. That is, a beam is emitted at the angle corresponding to the position of the first laser source in the array (see, e.g., FIG. 19A). If an object is in the region of view and reflects the beam, receiving structure 16 may detect the reflected beam. At step 130, controller 22 times the interval between the emission of the beam by emitting structure 14 and the detection of a reflected beam by receiving structure 16. At step 132, controller 22 computes the distance between the automobile or other environment in which laser ranging apparatus 10 is mounted and the object, based upon the time interval and the speed of light, i.e., a time-of-flight calculation. Controller 22 also can readily determine the relative bearing of the object because the bearing corresponds to the angle at which the beam was emitted. In the embodiment described above, the beam angle is related to the position of the emitting laser source in the array. Thus, at step 134 controller 22 can output the range and bearing of the object. As noted above, other systems (not shown) can use the range and bearing information in the conventional manner for aiding collision avoidance, parking assistance, turning assistance, cruise control or any other function for which conventional laser-based ranging systems have been used in the prior art.

It will be apparent to those skilled in the art that various modifications and variations can be made to this invention without departing from the spirit or scope of the invention. Thus, it is intended that the present invention cover all modifications and variations of this invention that they come within the scope of one or more claims and their equivalents. With regard to the claims, no claim is intended to invoke the sixth paragraph of 35 U.S.C. Section 112 unless it includes the term “means for” followed by a participle.

What is claimed is:

1. A laser ranging apparatus, comprising:
an emitting structure comprising a vertical-cavity surface-emitting laser (VCSEL) structure, the VCSEL structure comprising a plurality of laser sources formed upon a substantially planar monolithic substrate and disposed substantially in a plane of the substrate to emit beams along laser axes substantially normal to the plane and substantially parallel to one another, the emitting structure further comprising a corresponding plurality of optical elements, each optical element re-directing a corresponding beam along a beam axis to fan the beams out over a region of view;
a receiving structure comprising a detector disposed in an orientation to receive and detect beams reflected from objects in the region of view upon which the redirected beams impinge; and
a controller for electronically controlling the emitting and receiving structures to detect objects in the region of view.

2. The laser ranging apparatus claimed in claim 1, wherein the VCSEL structure comprises at least three of said laser sources.

3. The laser ranging apparatus claimed in claim 2, wherein the VCSEL structure comprises between 50 and 100 of said laser sources.

4. The laser ranging apparatus claimed in claim 1, wherein the emitting structure comprises a plurality of said VCSEL structures.

5. The laser ranging apparatus claimed in claim 1, wherein each beam is redirected along a beam axis not parallel to a beam axis along which any other of, said beams is redirected.

6. The laser ranging apparatus claimed in claim 5, wherein the laser sources are formed in an array, and a difference between the angle at which a beam emitted from one of the laser sources is redirected and an angle at which a beam emitted from another of the laser sources adjacent to the one of the laser sources is redirected is less than the difference between the angle at which a beam emitted from the one of the laser sources is redirected and angles at which beams emitted from laser sources not adjacent to the one of the laser sources are redirected.

7. The laser ranging apparatus claimed in claim 1, wherein the optical elements are microlenses formed upon the substrate.

8. The laser ranging apparatus claimed in claim 7, wherein:
the laser sources are formed in a first array upon the substrate at a first pitch defining a first separation between each laser source and an adjacent laser source in the array; and
the microlenses are formed in a second array upon the substrate at a second pitch defining a second separation between each microlens and an adjacent microlens in the array.

9. The laser ranging apparatus claimed in claim 8, wherein the second pitch is different from the first pitch.

10. The laser ranging apparatus claimed in claim 9, wherein the second pitch is greater than the first pitch.

11. A laser ranging method, comprising the steps of:
sequentially emitting beams from a vertical-cavity surface-emitting laser (VCSEL) structure, the VCSEL structure comprising a plurality of laser sources formed upon a substantially planar monolithic substrate and disposed substantially in a plane of the substrate, the beams emitted along laser axes substantially normal to the plane and substantially parallel to one another;
each of a plurality of optical elements re-directing a corresponding beam along a beam axis to fan the beams out over a region of view; and
detecting beams reflected from objects in the region of view upon which the redirected beams impinge.

12. The laser ranging method claimed in claim 11, wherein each beam is redirected along a beam axis not parallel to a beam axis along which any other of said beams is redirected.

13. The laser ranging method claimed in claim 11, wherein the VCSEL structure comprises an array of successive laser sources, and the step of sequentially emitting beams comprises successive laser sources in the array correspondingly emitting beams.

14. A method for making a laser ranging apparatus, comprising:
forming a vertical-cavity surface-emitting laser (VCSEL) structure and a plurality of optical elements upon a substantially planar monolithic substrate, the VCSEL structure comprising a plurality of laser sources in a first array disposed substantially in a plane of the substrate to emit beams along laser axes substantially normal to the plane and substantially parallel to one another, the plurality of optical elements formed in a second array, each optical element disposed to re-direct a corresponding beam along a beam axis to fan the beams out over a region of view; and
providing a receiving structure comprising a detector disposed in an orientation to receive and detect beams reflected from objects in the region of View upon which the redirected beams impinge.

15. The method for making a laser ranging apparatus claimed in claim 14, wherein the step of forming a VCSEL structure and a plurality of optical elements comprises forming the laser sources at a first pitch defining a first separation between each laser source and an adjacent laser source in the first array and forming the optical elements at a second pitch defining a second separation between each optical element and an adjacent optical element in the second array.

16. The method for making a laser ranging apparatus claimed in claim 14, wherein the step of forming a VCSEL structure and a plurality of optical elements comprises forming a microlens array.
